(19) United States
(12) Patent Application Publication
(10) Pub. No.: US 2021/0215434 A1
(43) Pub. Date: Jul. 15, 2021

(54) THIN TYPE VAPOR CHAMBER AND METHOD FOR MAKING THE SAME

(71) Applicant: TAIWAN MICROLOOPS CORP., New Taipei City (TW)

(72) Inventors: Yuan-San CHAO, New Taipei City (TW); Chun-Hung LIN, New Taipei City (TW)

(21) Appl. No.: 16/744,072

(22) Filed: Jan. 15, 2020

(51) Int. Cl. F28D 15/04; F28D 15/02

(52) U.S. Cl. CPC F28D 15/043; B23K 20/02; F28D 15/0283

(57) ABSTRACT

A vapor chamber includes a first metal plate, a second metal plate and a working fluid. The first metal plate is formed with a wick structure and a support structure having support elements. The second metal plate correspondingly covers and is fixed onto the first metal plate by a diffusion bonding technology. An end of each support element is in contact with the second metal plate. A chamber is formed between the first metal plate and the second metal plate. The working fluid is disposed in the chamber.

### BACKGROUND OF THE INVENTION

### Technical Field

The invention relates to heat dissipation technology, particularly to a thin type vapor chamber and a method for making the same.

### Related Art

With continuous increase of operational speed of electronic components, heat generated therefrom also becomes higher and higher. To solve this problem, vapor chambers with great heat transfer property have been provided to electronic components to implement heat transfer. However, current vapor chambers still have drawbacks in both heat transfer and thinning.

A conventional vapor chamber includes an upper plate, a lower plate, a wick structure and a working fluid. When manufacturing, the wick structure is disposed inside both the upper plate and the lower plate first, then combine the upper plate and the lower plate by welding to form a chamber between the upper plate and the lower plate, next inject the working fluid into the chamber, and finally, perform degassing and sealing to finish a vapor chamber.

However, such a vapor chamber has an effect of heat transfer, but there are drawbacks. The two plates are combined by welding their peripheries, the joint between the two plates tends to generate stress effect and deformation. Also, processing the wick structure and welding makes the manufacture complicated and difficult. Further, a vapor chamber made by the above process cannot reduce in overall thickness.

### SUMMARY OF THE INVENTION

An object of the invention is to provide a thin type vapor chamber and a method for making the same, which makes the manufacturing process easy and avoids deformation of metal plates.

To accomplish the above object, the invention provides a thin type vapor chamber including a first metal plate, a second metal plate and a working fluid. The first metal plate is formed with a wick structure and a support structure having support elements. The second metal plate correspondingly covers and is fixed onto the first metal plate by a diffusion bonding technology. An end of each support element is in contact with the second metal plate. A chamber is formed between the first metal plate and the second metal plate. The working fluid is filled in the chamber.

To accomplish the above object, the invention provides a method for making a thin type vapor chamber. The method includes the steps of: a) providing a first metal plate and a second metal plate; b) forming a wick structure and a support structure by etching, wherein the support structure comprises support elements; c) correspondingly combining the second metal plate and the first metal plate by a diffusion bonding technology, wherein an end of each support element is in contact with the second metal plate, and a chamber is formed between the first metal plate and the second metal plate; and d) injecting a working fluid in the chamber and performing degassing and sealing.

The invention also has the following functions. No soldering agent is needed in the assembling process to save material costs. When the first metal plate and the second metal plate have been assembled by the diffusion bonding technology, their junction is strong, deformation of the junction can be reduced and no stress effect occurs.

### BRIEF DESCRIPTION OF THE DRAWINGS

FIG. 1 is a perspective view of the first metal plate of the invention;

FIG. 2 is a partially enlarged view of FIG. 1;

FIG. 3 is a top plan view of the first metal plate of the invention;

FIG. 4 is an exploded view of the first metal plate and the second metal plate of the invention;

FIG. 5 is an assembled cross-section view of the thin type vapor chamber of the invention;

FIG. 6 is an exploded view of another embodiment of the invention;

FIG. 7 is an assembled cross-section view of another embodiment of the invention;

FIG. 8 is an assembled cross-section view of still another embodiment of the invention; and

FIG. 9 is a flowchart of the method for making the thin type vapor chamber of the invention.

### DETAILED DESCRIPTION OF THE INVENTION

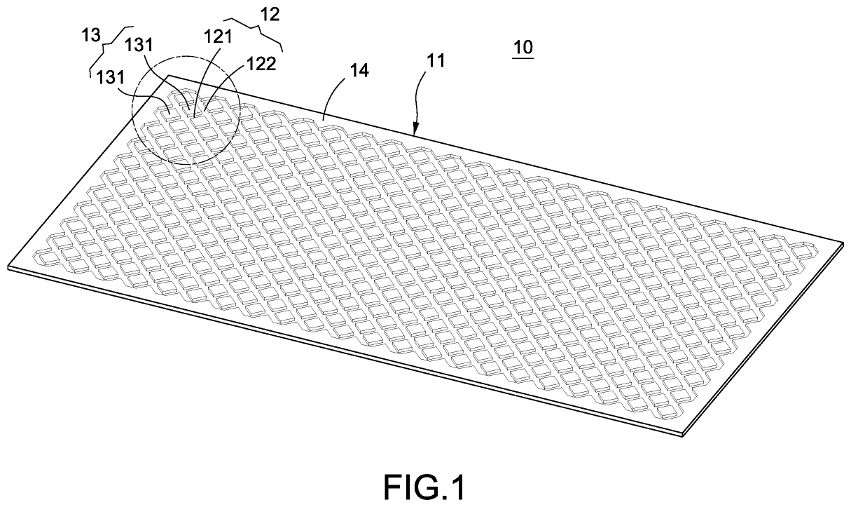

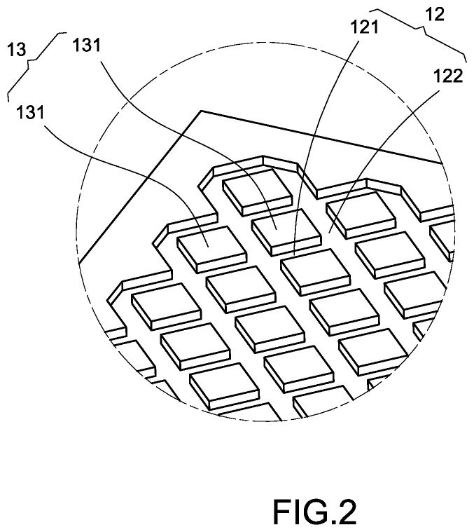

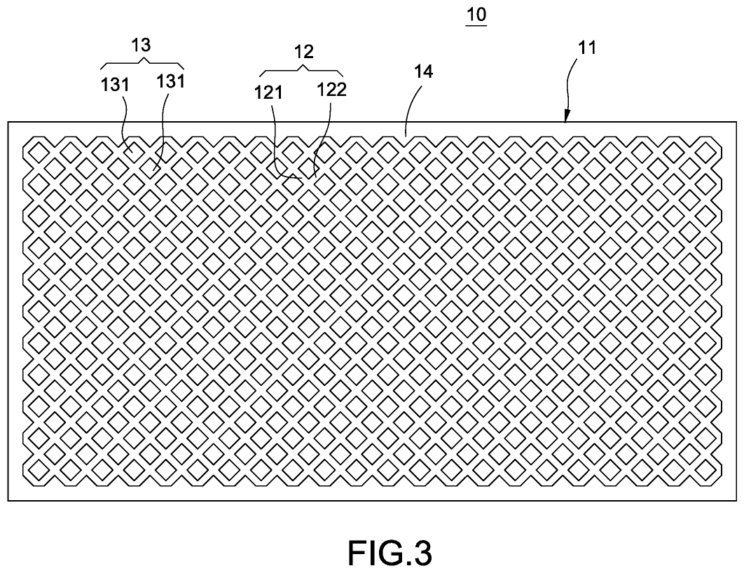

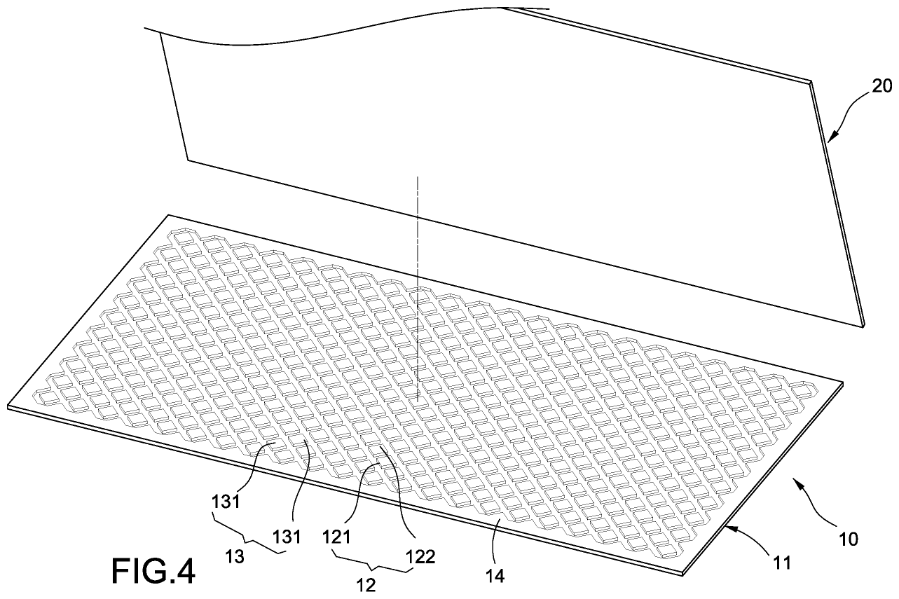

Please refer to FIGS. 1-5. The invention provides a thin type vapor chamber. The term “thin type” means an overall thickness between 0.6 mm and 2.2 mm, preferably between 1.0 mm and 2.0 mm. The thin type vapor chamber includes a first metal plate 10, a second metal plate 20 and a working fluid 30.

The first metal plate 10 may be made of aluminum, copper or their alloy and includes a substrate 11. A surface of the substrate 11 is formed with a wick structure 12 by chemical or physical etching. The wick structure 12 in this embodiment consists of first grooves 121 and second grooves 122. Each first groove 121 and each second groove 122 are arranged aslant interlaced. A support structure 13 is formed between each first groove 121 and each second groove 122. The support structure 13 includes support elements 131. In this embodiment, the support element 131 is substantially a cuboid block, but not limited to this.

Furthermore, a periphery to be connected 14 is formed on the substrate 11 outside the wick structure 12 and the support structure 13. In this embodiment, the periphery to be connected 14 is a substantially rectangular hollow frame, and a thickness of the periphery to be connected 14 is the same as that of each support element 131.

The second metal plate 20 may also be made of aluminum, copper or their alloy. The second metal plate 20 in this embodiment is a flat sheet and correspondingly covers and is fixed onto the first metal plate 10 by a diffusion bonding technology. An end of each support element 131 is in contact with the second metal plate 20. A chamber is formed between the first metal plate 10 and the second metal plate 20. The chamber is composed of the first grooves 121 and the second grooves 122. The diffusion bonding technology makes both the periphery to be connected 14 and ends of the support elements 131 attached to and connected to the second metal plate 20 without the third medium (such as solder or flux).

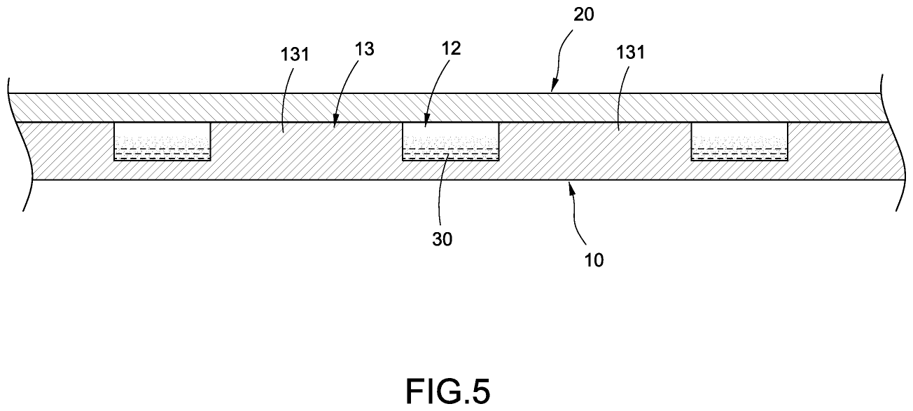

The working fluid 30 may be pure water (as shown in FIG. 5) and is injected in all of the first grooves 121 and the second grooves 122.

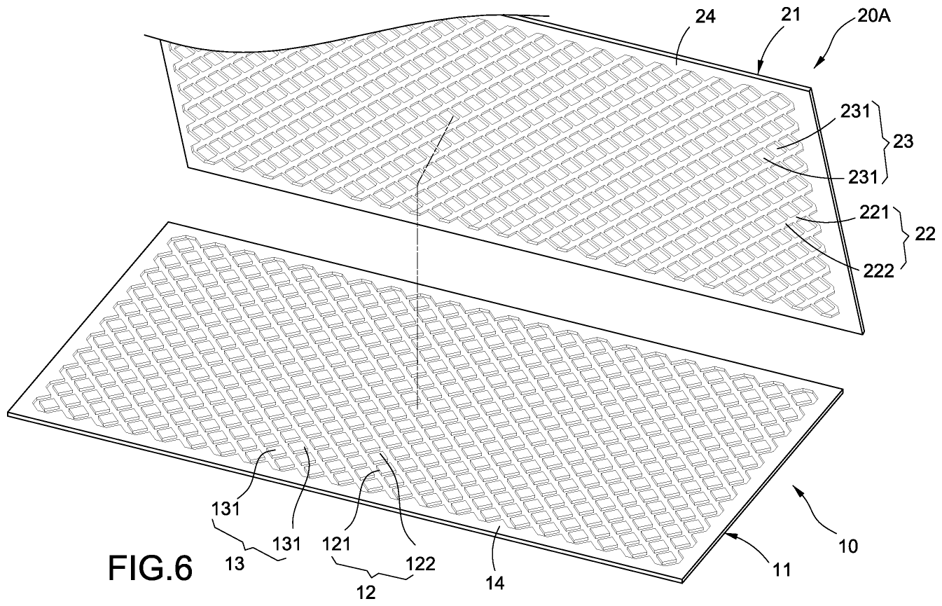

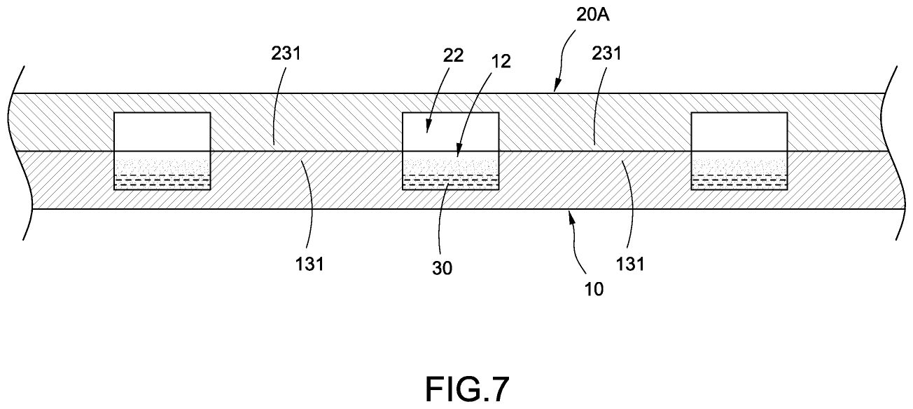

Please refer to FIGS. 6-7. The second metal plate 20A of another embodiment includes a substrate 21. A surface of the substrate 21 is formed with a wick structure 22 by chemical or physical etching. The wick structure 12 in this embodiment consists of first grooves 221 and second grooves 222. Each first groove 221 and each second groove 222 are arranged aslant interlaced. A support structure 23 is formed between each first groove 221 and each second groove 222. The support structure 23 includes support elements 231. In this embodiment, the support element 231 is a substantially cuboid block, but not limited to this. A periphery to be connected 24 is formed on the substrate 21 outside the wick structure 22 and the support structure 23. In this embodiment, the periphery to be connected 24 is a substantially rectangular hollow frame, and a thickness of the periphery to be connected 24 is the same as that of each support element 231.

The second metal plate 20 in this embodiment is a flat sheet and correspondingly covers and is fixed onto the first metal plate 10 by a diffusion bonding technology so as to make both the periphery to be connected 14, 24 and ends of the support elements 131, 231 attached to and connected with each other without the third medium.

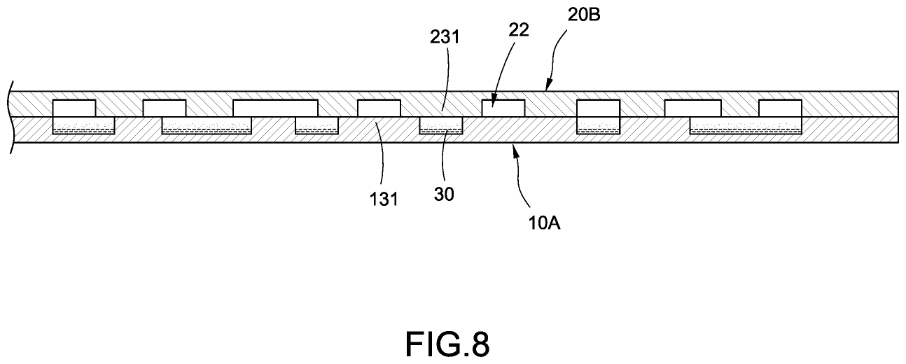

Please refer to FIG. 8. The first metal plate 10A in this embodiment has the support elements 131 and related structure as the above embodiment, but the first grooves and the second grooves of the wick structure 22 are arranged at irregular intervals, so that ends of a part of the support elements 231 are in contact with the support elements of the first metal plate 10 and another part of the support elements 231 are formed between each first grooves and/or each second groove.

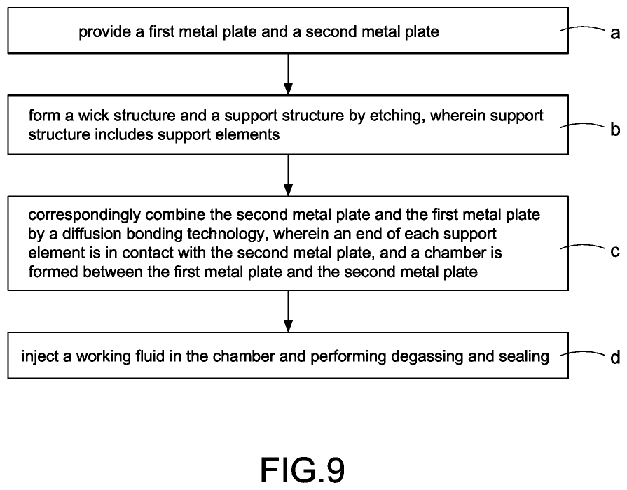

Please refer to FIG. 9. The invention further provides a method for making a thin type vapor chamber, which includes the steps of:

a) providing a first metal plate 10 and a second metal plate 20;

b) forming a wick structure 12 and a support structure 13 by etching, wherein support structure 13 includes support elements 131;

c) correspondingly combining the second metal plate 20 and the first metal plate 10 by a diffusion bonding technology, wherein an end of each support element 131 is in contact with the second metal plate 20, and a chamber is formed between the first metal plate 10 and the second metal plate 20; and

d) injecting a working fluid 30 in the chamber and performing degassing and sealing.

It will be appreciated by persons skilled in the art that the above embodiments have been described by way of example only and not in any limitative sense, and that various alterations and modifications are possible without departure from the scope of the invention as defined by the appended claims.

What is claimed is:

1. A thin type vapor chamber comprising:
a first metal plate, formed with a wick structure and a support structure having support elements;
a second metal plate, correspondingly covering and being fixed onto the first metal plate by a diffusion bonding technology, an end of each support element being in contact with the second metal plate, and a chamber being formed between the first metal plate and the second metal plate; and
a working fluid disposed in the chamber.

2. The thin type vapor chamber of claim 1, wherein the first metal plate comprises a substrate, and both the wick structure and the support structure are formed on a surface of the substrate.

3. The thin type vapor chamber of claim 2, wherein the wick structure comprises first grooves and second grooves, and each first groove and each second groove are arranged aslant interlaced.

4. The thin type vapor chamber of claim 3, wherein each support element is formed between each first groove and each second groove.

5. The thin type vapor chamber of claim 2, wherein a periphery to be connected is formed on the substrate outside the wick structure and the support structure, and the periphery to be connected is an annular frame.

6. The thin type vapor chamber of claim 5, wherein a thickness of the periphery to be connected is the same as that of each support element.

7. The thin type vapor chamber of claim 1, wherein the second metal plate is a flat sheet.

8. The thin type vapor chamber of claim 1, wherein the second metal plate comprises a substrate, a surface of the substrate is formed with a wick structure and a support structure, and the support structure of the second metal plate comprises support elements.

9. The thin type vapor chamber of claim 8, wherein the wick structure and the support elements of the second metal plate are arranged to align with the wick structure and the support elements of the first metal plate, respectively.

10. The thin type vapor chamber of claim 8, wherein the wick structure and the support elements of the second metal plate are arranged not to align with the wick structure and the support elements of the first metal plate, respectively.

11. The thin type vapor chamber of claim 8, wherein the wick structure of the second metal plate comprises first grooves and second grooves, and each first groove and each second groove are arranged aslant interlaced.

12. The thin type vapor chamber of claim 11, wherein each support element of the second metal plate is formed between each first groove and each second groove.

13. The thin type vapor chamber of claim 11, wherein a periphery to be connected is formed on the second metal plate outside the wick structure and the support structure, and the periphery to be connected is an annular frame.

14. The thin type vapor chamber of claim 13, wherein a thickness of the periphery to be connected of the second metal plate is the same as that of each support element.

15. A method for making a thin type vapor chamber, comprising:
a) providing a first metal plate and a second metal plate;
b) forming a wick structure and a support structure by etching, wherein support structure comprises support elements;
c) correspondingly combining the second metal plate and the first metal plate by a diffusion bonding technology, wherein an end of each support element is in contact with the second metal plate, and a chamber is formed between the first metal plate and the second metal plate; and
d) injecting a working fluid in the chamber and performing degassing and sealing.

16. The method of claim 15, wherein the first metal plate comprises a substrate, both the wick structure and the support structure are formed on a surface of the substrate, the wick structure comprises first grooves and second grooves, and each first groove and each second groove are arranged aslant interlaced.

17. The method of claim 16, wherein each support element is formed between each first groove and each second groove.

18. The method of claim 15, wherein a periphery to be connected is formed on the substrate outside the wick structure and the support structure, and the periphery to be connected is an annular frame.

19. The method of claim 18, wherein a thickness of the periphery to be connected is the same as that of each support element.

20. The method of claim 15, wherein the second metal plate is a flat sheet.
